(19) United States
(12) Patent Application Publication
(10) Pub. No.: US 2026/0036635 A1
(43) Pub. Date: Feb. 5, 2026

(54) METHOD AND SYSTEM FOR MONITORING STATUS OF BATTERY

(71) Applicant: Samsung SDI Co., Ltd., Yongin-si (KR)

(72) Inventor: Jonghun Lee, Yongin-si (KR)

(73) Assignee: Samsung SDI Co., Ltd., Yongin-si (KR)

(21) Appl. No.: 19/002,402

(22) Filed: Dec. 26, 2024

(30) Foreign Application Priority Data
Jul. 30, 2024 (KR) 10-2024-0101302

(51) Int. Cl. G01R 31/3835; G01R 31/374; G01R 31/392; G01R 31/396

(52) U.S. Cl. CPC G01R 31/3835; G01R 31/374; G01R 31/392; G01R 31/396

(57) ABSTRACT

The present disclosure provides a method for monitoring a status of a battery. The method including obtaining measurement data for a plurality of battery modules included in a battery rack, dividing the battery modules into a plurality of groups, based on the measurement data, obtaining voltage data for each battery cell in each battery module included in the plurality of groups, and detecting a suspected abnormal cell among the battery cells included in the plurality of groups, based on the voltage data.

### CROSS-REFERENCE TO RELATED APPLICATIONS

This present application claims priority to and the benefit under 35 U.S.C. § 119(a)-(d) of Korean Patent Application No. 10-2024-0101302, filed on Jul. 30, 2024, in the Korean Intellectual Property Office, the entire disclosure of which is incorporated herein by reference.

### FIELD

Aspects of embodiments of the present disclosure relate to a method and system for monitoring a status of a battery.

### BACKGROUND

In general, an energy storage system (ESS) refers to a device that improves power usage efficiency by storing surplus electricity, or stores energy produced through renewable energy in a storage device (e.g., a battery) and then supplies the energy if necessary. An energy storage device is composed of a battery, a battery management system (BMS) for monitoring the status of the battery and controlling and operating the battery, a power conversion system (PCS) for charging and discharging the battery, and a battery control unit (BCU) for communicating with the BMS and PCS to diagnose the energy storage device and control charging and discharging.

In general, an energy storage device is used such that a plurality of battery racks, in which battery modules that are a collection of multiple battery cells are arranged and accommodated in a vertical direction, i.e., a longitudinal direction, are arranged and connected in a horizontal direction. The battery modules are connected by being stacked vertically. The battery modules are electrically connected in a vertical direction, i.e., a longitudinal direction. The battery modules are gathered to form a single rack. These racks are electrically connected to each other again to form a single large battery storage device.

Meanwhile, the BMS includes a module BMS for controlling a plurality of battery modules, a rack BMS for controlling the module BMSs, a system BMS for controlling the rack BMSs, and a battery controller for interfacing the system BMS with an upper controller, and serves to provide power stored in the battery modules to the system or charge power of the system to the batteries. The rack BMS monitors cell voltage deviations so as to detect deterioration of battery cells in the battery module. That is, in a case where the deviation between a maximum cell voltage and a minimum cell voltage within the rack is greater than a certain value, an alarm/protection is generated, charging and discharging are stopped, and action is requested from the user.

The above information disclosed in this Background section is for enhancement of understanding of the background of the present disclosure, and therefore, it may contain information that does not constitute related (or prior) art.

### SUMMARY

Aspects of embodiments of the present disclosure provide a method and system for monitoring a status of a battery so as to solve problems described herein.

However, the technical problem to be solved by the present disclosure is not limited to the above problem, and other problems not mentioned herein, and aspects and features of the present disclosure that would address such problems, will be clearly understood by those skilled in the art from the description of the present disclosure below.

Aspects of embodiments provide a method for monitoring a status of a battery, the method including: obtaining measurement data for a plurality of battery modules included in a battery rack; dividing the battery modules into a plurality of groups, based on the measurement data; obtaining voltage data for each battery cell in each battery module included in the plurality groups; and detecting a suspected abnormal cell among the battery cells included in the plurality of groups, based on the voltage data.

According to one embodiment, the measurement data may include temperature data, and the dividing may include dividing the battery modules into a plurality of groups, based on a temperature distribution of the temperature data.

According to one embodiment, the measurement data may include temperature data, and the dividing may include dividing the battery modules into a plurality of groups at a preset temperature interval.

According to one embodiment, the preset temperature interval may be 0.5° C. to 1° C.

According to one embodiment, the measurement data may include state of health (SOH) data, and the dividing may include dividing the battery cells into a plurality of groups at a preset SOH interval.

According to one embodiment, the preset SOH interval may be 5% to 10%.

According to one embodiment, the detecting of the suspected abnormal cell may include: sorting the voltage data in order of magnitude within a same group, based on the voltage data obtained in the obtaining of the voltage data; determining whether the voltage data for a memory sorted in the sorting of the voltage data in order of magnitude may be a maximum value or a minimum value; and determining the memory cell as a suspected abnormal cell in a case where it may be determined that the voltage data of the memory cell corresponds to the maximum value or the minimum value.

According to one embodiment, the detecting of the suspected abnormal cell may include: calculating a median value of the voltage data within a same group, based on the voltage data obtained in the obtaining of the voltage data; determining whether a deviation from the median value of the voltage data calculated in the calculating of the median value may be largest for a memory cell; and determining the memory cell as a suspected abnormal cell in a case where the deviation from the median value of the voltage data for the memory cell may be determined to be largest.

According to one embodiment, the detecting of the suspected abnormal cell may include: calculating a voltage deviation between voltage data for a memory cell and maximum voltage data and minimum voltage data within a same group, based on the voltage data obtained in the obtaining of the voltage data; and determining the memory cell as a suspected abnormal cell in a case where the voltage deviation calculated in the calculating of the voltage deviation may be greater than a preset reference value.

According to one embodiment, the obtaining of the voltage data may include storing identifier information and voltage data for each battery cell in the battery modules.

According to one embodiment, the battery modules are connected through respective rack battery management systems (BMSs), and the dividing may include dividing the battery modules connected through the respective rack BMSs into a plurality of groups.

According to one embodiment, the respective rack BMSs are connected through a system BMS, and the dividing may include dividing, by the system BMS, the battery modules connected through the respective rack BMSs into a plurality of groups.

According to one embodiment, may further include, after the detecting of the suspected abnormal cell, displaying identifier information of the detected suspected abnormal cell on a display unit.

Aspects of embodiments further provide a system for monitoring a status of a battery, the system including: at least one battery rack for a plurality of battery modules in which a plurality of battery cells are electrically connected, and at least one rack battery management systems (BMS) configured to manage charging and discharging of the plurality of battery modules; and a system BMS connected to the at least one rack BMS and configured to divide the plurality of battery modules included in the at least one battery rack into a plurality of groups and detect a suspected abnormal cell.

According to one embodiment, the system BMS may include: a data collection unit configured to obtain measurement data for the plurality of battery modules; a grouping unit configured to divide the plurality of battery modules into a plurality of groups, based on the measurement data; an abnormal cell detection unit configured to obtain voltage data for each battery cell included in the groups and detect a suspected abnormal cell among the battery cells included in the groups, based on the voltage data.

According to one embodiment, the measurement data may include temperature data, and the grouping unit may be configured to divide the battery modules into a plurality of groups at a preset temperature interval.

According to one embodiment, the measurement data may include state of health (SOH) data, and the grouping unit may be configured to divide the battery cells into a plurality of groups at a preset SOH interval.

According to one embodiment, the abnormal cell detection unit may be configured to detect a suspected abnormal cell based on voltage data for each battery cell in each battery module included in a same group.

According to one embodiment, each battery module may include a module BMS configured to measure physical quantities of the battery cells and transmit measured data to the at least one rack BMS.

According to one embodiment, may further include a display unit connected to the system BMS and configured to display identifier information of the detected suspected abnormal cell.

According to some embodiments of the present disclosure, the maximum deteriorated cell or the suspected abnormal cell may be detected more accurately and quickly in the device including the battery modules or battery cells, such as an energy storage system.

However, aspects and features of the present disclosure are not limited to those described above, and other aspects and features not mentioned will be clearly understood by a person skilled in the art from the detailed description, described below.

### BRIEF DESCRIPTION OF THE DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings.

FIG. 1 illustrates a perspective view of a battery rack of a system for monitoring a status of a battery according to an embodiment of the present disclosure.

FIG. 2 illustrates a perspective view of a battery module of a system for monitoring a status of a battery according to an embodiment of the present disclosure.

FIG. 3 illustrates a conceptual diagram of a system for monitoring a status of a battery according to an embodiment of the present disclosure.

FIG. 4 illustrates a conceptual diagram showing a configuration of a system BMS of FIG. 3.

FIG. 5 illustrates a system for monitoring a status of a battery according to an embodiment of the present disclosure, which is divided into a plurality of groups based on temperature data.

FIG. 6 illustrates a system for monitoring a status of a battery according to another embodiment of the present disclosure, which is divided into a plurality of groups based on SOH data.

FIG. 7 illustrates a conceptual diagram illustrating a system for monitoring a status of a battery, including a display unit, according to an embodiment of the present disclosure.

FIG. 8 illustrates a flowchart showing a method for monitoring a status of a battery according to an embodiment of the present disclosure.

FIG. 9 illustrates a flowchart showing a method for monitoring a status of a battery according to another embodiment of the present disclosure.

FIG. 10 illustrates a detailed flowchart showing an embodiment of an abnormal cell detection step in the method for monitoring a status of a battery illustrated in FIG. 8.

FIG. 11 illustrates a detailed flowchart illustrating another embodiment of an abnormal cell detection step in the method for monitoring a status of a battery illustrated in FIG. 8.

### DETAILED DESCRIPTION

Hereinafter, embodiments of the present disclosure will be described, in detail, with reference to the accompanying drawings. The terms or words used in the present specification and claims are not to be limitedly interpreted as general or dictionary meanings and should be interpreted as meanings and concepts that are consistent with the technical idea of the present disclosure on the basis of the principle that an inventor can be his/her own lexicographer to appropriately define concepts of terms to describe his/her invention in the best way.

The embodiments described in this specification and the configurations shown in the drawings are only some of the embodiments of the present disclosure and do not represent all of the technical spirit, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A,

B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

The terms used in the present specification are for describing embodiments of the present disclosure and are not intended to limit the present disclosure.

In addition, a battery management system (BMS) and/or other related devices or components according to the present disclosure may be implemented using any suitable hardware, firmware (e.g., application-specific integrated circuits), software, or a suitable combination of software, firmware, and hardware. For example, various elements of the BMS and/or other related devices or components according to the present disclosure may be formed on one integrated circuit chip or on separate integrated circuit chips. In addition, various elements of the BMS may be implemented on a flexible printed circuit film and may be formed on a tape carrier package, a printed circuit board, or the same substrate as the BMS. In addition, various elements of the BMS may be processes or threads running on one or more processors in one or more computing devices, which may execute computer program instructions and interact with other elements so as to perform various functions described herein. The computer program instructions are stored in a memory that may be implemented in a computing device by using a standard memory device, such as random access memory. The computer program instructions may also be stored in other non-transitory computer readable media, such as, for example, CD-ROM, flash drive, etc. In addition, those of ordinary skill in the art should recognize that the functions of various computing devices may be combined with each other or integrated into a single computing device, or the functions of a particular computing device may be distributed over one or more other computing devices without departing from the embodiments of the present disclosure.

Although battery modules connected to the rack are charged and discharged at the same current, the degree of deterioration may vary depending on the ambient temperature of each module for reasons such as air conditioning or internal resistance. As the usage time of battery modules increases, the degree of deterioration increases, and eventually the rack BMS detects deterioration targeting battery modules with different degrees of deterioration. Although the most deteriorated cell may be detected in the rack, there is a problem in that modules with similar deterioration states cannot be compared.

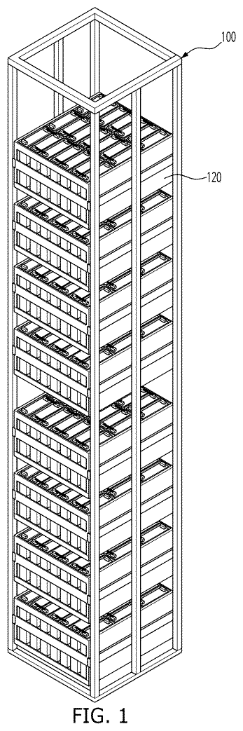

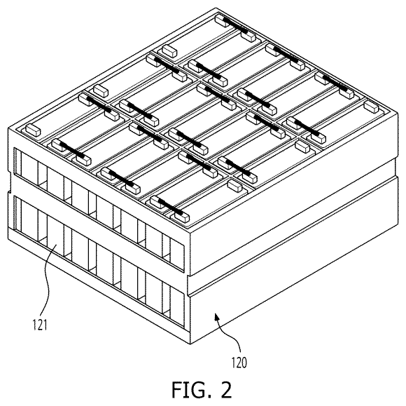

FIG. 1 illustrates a perspective view of a battery rack of a system for monitoring a status of a battery according to an embodiment of the present disclosure, and FIG. 2 illustrates a perspective view of a battery module of a system for monitoring a status of a battery according to an embodiment of the present disclosure.

Referring to FIGS. 1 and 2, the system for monitoring a status of a battery according to an embodiment may include a plurality of battery modules 120 and a battery rack 100 that accommodates the battery modules 120. In FIG. 1, eight battery modules 120 are accommodated in the battery rack 100, but this is only an example, and the present disclosure may be applied to an energy storage device in which one or more battery modules 120 are accommodated in the battery rack 100.

Each of the battery modules 120 is an assembly in which a plurality of battery cells 121 are connected in series or in parallel, and may include the battery cells 121 and a frame that accommodates the battery cells 121. FIG. 2 illustrates a case where the battery cells 121 are connected in series, but the present disclosure is not limited thereto, and the battery cells 121 may be appropriately connected in series and/or in parallel so as to obtain a desired capacity or output.

The battery cell 121 is a secondary battery and can be charged and discharged. The battery cell 121 is a stacked or wound electrode assembly with a separator between a positive electrode and a negative electrode, and is sealed in a case together with an electrolyte. The battery cell 121 may be any battery having a configuration that can generate electrochemical energy by reacting with an electrolyte, and may be, for example, a lithium polymer battery or a lithium ion battery. A specific configuration of the battery cell 121 is known, and thus, a detailed description thereof is omitted.

The battery module 120 may connect the battery cells 121 in series by using a plurality of connection terminals. One connection terminal electrically connects the negative terminal of one battery cell 121 to the positive terminal of another battery cell 121, and in this manner, the battery cells 121 may be connected in series. However, as described herein, the present disclosure is not limited thereto, and the battery cells 121 may be connected in parallel or in series/parallel by the connection terminals. The battery cells 121 may be accommodated in the battery module 120 to form a plurality of rows.

The frame of the battery module 120 may accommodate and protect the battery cells 121 and may be detachably fixed to the battery rack 100. For example, the battery rack 100 may be a cabinet that accommodates the eight battery modules 120. A battery monitoring system according to an embodiment may include at least one battery rack 100, wherein the battery racks may be electrically connected to each other. The battery rack 100 may have high power terminals (positive and negative terminals) exposed to the outside, and the high power terminals of each battery rack 100 may be connected in parallel. The battery rack 100 may include a plurality of battery modules 120 in which the battery cells 121 are electrically connected. Each of the battery racks 100 may include a plurality of battery modules 120 electrically connected to each other. The battery modules 120 included in each of the battery racks 100 may be connected in series and/or in parallel. The battery modules 120 may be accommodated along the height direction of the battery rack 100.

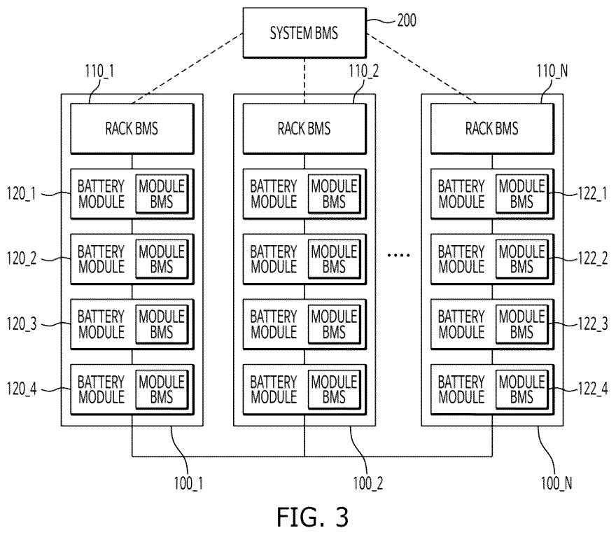

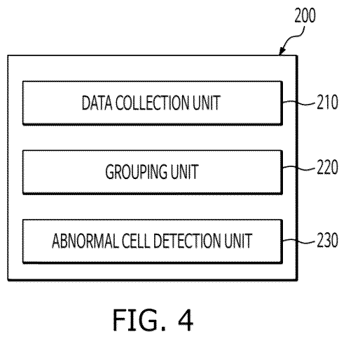

FIG. 3 illustrates a conceptual diagram of a system for monitoring a status of a battery according to an embodiment of the present disclosure, and FIG. 4 illustrates a conceptual diagram showing a configuration of a system BMS of FIG. 3.

Referring to FIGS. 3 and 4, the system for monitoring a status of a battery according to an embodiment may include one or more battery racks 100_1, 100_2, . . . , and 100_N respectively including rack BMSs 110_1, 110_2, . . . , and 110_N, and a system BMS 200.

The battery racks 100_1, 100_2, . . . , and 100_N may respectively include the rack BMSs 110_1, 110_2, . . . , and 110_N that manage charging and discharging of the battery modules 120_1, 120_2, 120_3, and 120_4. Each of the rack BMSs 110_1, 110_2, . . . , and 110_N may be connected to the battery modules 120_1, 120_2, 120_3, and 120_4 composed of a plurality of battery cells 121 and configured to monitor the status of the battery cells in the corresponding battery modules 120_1, 120_2, 120_3, and 120_4. According to an embodiment illustrated in the drawing, the four battery modules 120_1, 120_2, 120_3, and 120_4 are included in each of the battery racks 100_1, 100_2, . . . , and 100_n, but the present disclosure is not particularly limited to the number of battery modules.

The system BMS 200 may be connected to the rack BMSs 110_1, 110_2, . . . , and 110_N, and may divide the battery modules 120_1, 120_2, 120_3, and 120_4 included in the battery racks 100_1, 100_2, . . . , and 100_N into a plurality of groups and detect suspected abnormal cells. In addition, the system BMS 200 may be configured to receive, from the one or more rack BMSs 110_1, 110_2, . . . , and 110_N, status information of the battery modules 120_1, 120_2, 120_3, and 120_4 or the battery cells associated with the rack BMSs 110_1, 110_2, . . . , and 110_N).

The system BMS 200 may include a data collection unit 210, a grouping unit 220, and an abnormal cell detection unit 230. In an embodiment, the data collection unit 210 may obtain measurement data for the battery modules 120_1, 120_2, 120_3, and 120_4. The grouping unit 220 may divide the battery modules 120_1, 120_2, 120_3, and 120_4 into a plurality of groups, based on the measurement data obtained by the data collection unit 210.

More specifically, the data collection unit 210 may separately store identifier information of the battery racks 100_1, 100_2, . . . , and 100_N, identifier information of the battery modules 120_1, 120_2, 120_3, and 120_4, identifier information of the battery cells, and voltage deviation of the battery cells at regular temperature value intervals, based on the temperature measured for each battery module or battery cell. The grouping unit 220 may group the battery modules 120_1, 120_2, 120_3, and 120_4 within a certain temperature value into the same group.

In an embodiment, the measurement data obtained by the data collection unit 210 may be temperature data. The data collection unit 210 may obtain temperature data for the battery modules 120_1, 120_2, 120_3, and 120_4. At this time, the grouping unit 220 may divide the battery modules 120_1, 120_2, 120_3, and 120_4 into a plurality of groups at preset specific temperature intervals.

In another embodiment, the measurement data obtained by the data collection unit 210 may be state of health (SOH) data. Each of the battery modules 120_1, 120_2, 120_3, and 120_4 may include module BMSs 122_1, 122_2, 122_3, and 122_4 that measure physical quantities of the battery cells and transmit the measured data to the rack BMSs 110_1, 110_2, . . . , and 110_N. Each of the battery modules 120_1, 120_2, 120_3, and 120_4 may include the module BMSs 122_1, 122_2, 122_3, and 122_4, and the module BMSs 122_1, 122_2, 122_3, and 122_4 may measure and/or control physical quantities (voltage, current, temperature, etc.) of the battery cells included in the battery modules 120_1, 120_2, 120_3, and 120_4, and may transmit the resulting data to the rack BMSs 110_1, 110_2, . . . , and 110_N in a case where the status of the battery cells determined based on the measured physical quantities is abnormal. In addition, the module BMSs 122_1, 122_2, 122_3, and 122_4 may monitor the lifespan the SOH of the battery cells included in the battery modules 120_1, 120_2, 120_3, and 120_4. The module BMSs 122_1, 122_2, 122_3, and 122_4 may perform cell balancing to prevent each battery cell from becoming an abnormal status such as overcharge, overdischarge, overcurrent, and overheating, thereby improving battery efficiency. The data collection unit 210 may obtain SOH data for the battery cells 121. At this time, the grouping unit 220 may divide the battery cells 121 into a plurality of groups at preset specific SOH intervals.

In an embodiment, the voltages and temperatures of the battery modules 120_1, 120_2, 120_3, and 120_4 and/or the battery cells included in the battery racks 100_1, 100_2, . . . , and 100_N may be measured by temperature and voltage sensors included in the battery modules 120_1, 120_2, 120_3, and 120_4 and transmitted to the module BMSs 122_1, 122_2, 122_3, and 122_4. In addition, the module BMSs 122_1, 122_2, 122_3, and 122_4 may transmit the temperature and voltage values of the battery modules 120_1, 120_2, 120_3, and 120_4 and/or the battery cells to the upper BMs, i.e., the rack BMSs 110_1, 110_2, . . . , and 110_N. That is, the rack BMSs 110_1, 110_2, . . . , and 110_N may receive the temperatures and voltages of the battery modules 120_1, 120_2, 120_3, and 120_4 and/or the battery cells included in the battery racks 100_1, 100_2, . . . , and 100_N. In addition, the rack BMSs 110_1, 110_2, . . . , and 110_N may transmit, to the system BMS 200, the temperature and voltage values of the battery modules 120_1, 120_2, 120_3, and 120_4 and/or the battery cells included in the battery racks 100_1, 100_2, . . . , and 100_N.

The abnormal cell detection unit 230 may obtain voltage data for each of the battery cells included in the groups classified by the grouping unit 220, and may detect suspected abnormal cells among the battery cells included in the groups based on the obtained voltage data. In an embodiment, the abnormal cell detection unit 230 may detect suspected abnormal cells based on the voltage data for each of the battery cells in the battery modules 120_1, 120_2, 120_3, and 120_4 included in the same group.

In an embodiment, the system for monitoring a status of a battery may be configured such that the system BMS 200 receives information related to the status of the battery cell 121 in a daisy chain manner from the one or more rack BMSs 110_1, 110_2, . . . , and 110_N. For example, each of the rack BMSs 110_1, 110_2, . . . , and 110_N may accumulate status information of a previous rack BMS and transmit the accumulated status information to a next rack BMS. For example, the first rack BMS 110_1 may receive status information of the battery modules included in the first battery rack 100_1 and transmit the received status information to the second rack BMS 110_2. In addition, the second rack BMS 110_2 may receive status information of the battery modules included in the first battery rack 100_1 and status information of the battery modules included in the second battery rack 100_2 and transmit the received status information to the next rack BMS 110_3. Finally, the N-th rack BMS 110_N may transmit, to the system BMS 200, status information of the battery modules included in the first battery rack 100_1 to status information of the battery modules included in the N-th battery rack 100_N. In another example, in a case where a subsequent rack BMS receives abnormal status information from a previous rack BMS, the subsequent rack BMS may serially transmit the abnormal status information to the system BMS 200. A specific method for transmitting status information of battery cells by using the daisy chain method is not limited to the above-described example and may be implemented in various ways.

According to an embodiment, in the system for monitoring a status of a battery, the rack BMSs 110_1, 110_2, . . . , and 110_N respectively included in the battery racks 100_1, 100_2, . . . , and 100_N may all be connected to the system BMS 200. The system BMS 200 may manage and control the rack BMSs 110_1, 110_2, . . . , and 110_N respectively included in the battery racks 100_1, 100_2, . . . , and 100_N. The system BMS 200 may be a master BMS, and the rack BMSs 110_1, 110_2, . . . , and 110_N and the module BMSs 122_1, 122_2, 122_3, and 122_4 may be slave BMSs, but the present disclosure is not limited thereto. In an embodiment, the respective rack BMSs 110_1, 110_2, . . . , and 110_N may be communicatively connected to the system BMS 200 via a communication line (e.g., controller area network (CAN) communication). For example, the rack BMSs 110_1, 110_2, . . . , and 110_N may transmit status information of the battery modules 120_1, 120_2, 120_3, and 120_4 to the system BMS 200 via a CAN communication module. In this case, all the rack BMSs 110_1, 110_2, . . . , and 110_N may communicate directly with the system BMS 200 via CAN communication.

The system BMS 200 may monitor the status of the battery cells based on status information such as voltage, current, and temperature of each battery cell received from the rack BMSs 110_1, 110_2, . . . , and 110_N. For example, the system BMS 200 may determine whether the battery cell is in an overvoltage or undervoltage state, based on at least one of status information such as voltage, current, and temperature of each battery cell. In another example, the system BMS 200 may detect the voltage difference between the battery cells, based on at least one of status information such as voltage, current, and temperature of each battery cell.

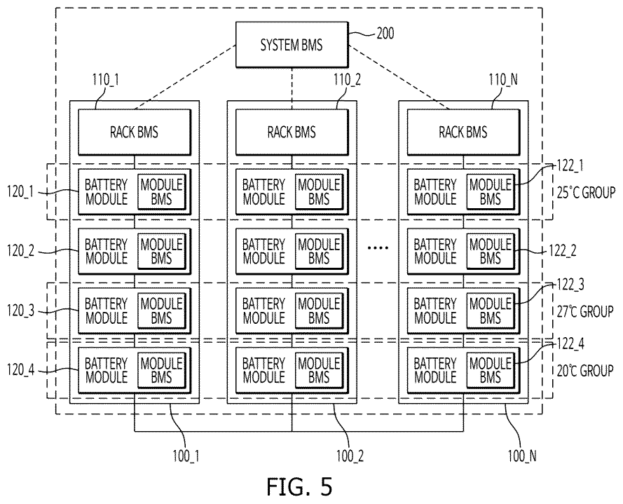

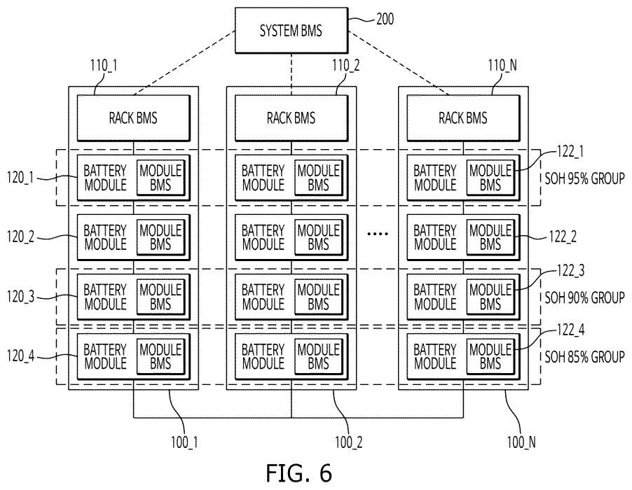

FIG. 5 illustrates a system for monitoring a status of a battery according to an embodiment of the present disclosure, which is divided into a plurality of groups based on temperature data, and FIG. 6 illustrates a system for monitoring a status of a battery according to another embodiment of the present disclosure, which is divided into a plurality of groups based on SOH data.

The system for monitoring a status of a battery according to an embodiment may detect suspected abnormal cells by dividing a plurality of battery modules 120_1, 120_2, 120_3, and 120_4 included in a plurality of battery racks 100_1, 100_2, . . . , and 100_N into a plurality of groups based on temperature data. That is, the battery modules 120_1, 120_2, 120_3, and 120_4 having similar deterioration states, each included in different battery racks 100_1, 100_2, . . . , and 100_N, may be grouped into one same group.

For example, as illustrated in FIG. 5, in a case where the battery modules 120_1 of identifier information number 1 among the battery modules of the first battery rack 100_1 and the second battery rack 100_2 to the N-th battery rack 100_N are within a temperature range of 25° C. to 25.9° C., the battery modules 120_1 may be determined to be in the same deterioration state and classified into the same 25° C. group. In addition, in a case where the battery modules 120_3 of identifier information number 3 among the battery modules of the first battery rack 100_1 and the second battery rack 100_2 to the N-th battery rack 100_N are within a temperature range of 27° C. to 27.9° C., the battery modules 120_3 may be determined to be in the same deterioration state and classified into the same 27° C. group. In addition, in a case where the battery modules 120_4 of identifier information number 4 among the battery modules of the first battery rack 100_1 and the second battery rack 100_2 to the N-th battery rack 100_N are within a temperature range of 20° C. to 20.9° C., the battery modules 120_3 may be determined to be in the same deterioration state and classified into the same 20° C. group.

Because the temperature distribution may vary depending on a user, place, or operating status of the system for monitoring a status of a battery, the criteria for dividing the group of battery modules may be changed according to a situation, such as classifying the group by dividing the difference between the highest temperature and the lowest temperature in each temperature distribution into N equal parts. For example, in a case where the highest temperature is 26.9° C. and the lowest temperature is 24.0° C., the first group may be composed of battery modules having a temperature between 24° C. and 24.9° C., the second group may be composed of battery modules having a temperature between 25° C. and 25.9° C., and the third group may be composed of battery modules having a temperature between 26° C. and 26.9° C.

A system for monitoring a status of a battery according to another embodiment may detect suspected abnormal cells by dividing a plurality of battery cells into a plurality of groups based on SOH data of the modules 120_1, 120_2, 120_3, and 120_4 included in the battery racks 100_1, 100_2, . . . , and 100_N. That is, the battery cells having similar deterioration states, each included in different battery racks 100_1, 100_2, . . . , and 100_N, may be grouped into one same group.

For example, as illustrated in FIG. 6, in a case where the lifespan of battery cells belonging to the battery modules 120_1 of identifier information number 1 among the battery modules of the first battery rack 100_1 and the second battery rack 100_2 to the N-th battery rack 100_N are within 95% SOH, the battery cells may be determined to be in the same lifespan state and classified into the same 95% group. In addition, in a case where the lifespan of battery cells belonging to the battery modules 120_3 of identifier information number 3 among the battery modules of the first battery rack 100_1 and the second battery rack 100_2 to the N-th battery rack 100_N are within 90% SOH, the battery cells may be determined to be in the same lifespan state and classified into the same 90% group. In addition, in a case where the lifespan of battery cells belonging to the battery modules 120_4 of identifier information number 3 among the battery modules of the first battery rack 100_4 and the second battery rack 100_2 to the N-th battery rack 100_N are within 85% SOH, the battery cells may be determined to be in the same lifespan state and classified into the same 85% group.

In the past, in a case of detecting suspected abnormal cells in units of battery racks, only the most deteriorated cell within one battery rack could be detected, but because battery modules with similar deterioration status could not be compared with each other, it took a relatively long time to find suspected abnormal cells. To solve these problems, a method for monitoring a status of a battery according to some embodiments of the present disclosure may divide battery modules having similar deterioration status between a plurality of battery racks into a plurality of groups based on predetermined criteria such as measured temperature or SOH, rather than in units of one battery rack, and then detect suspected abnormal cells more quickly and accurately.

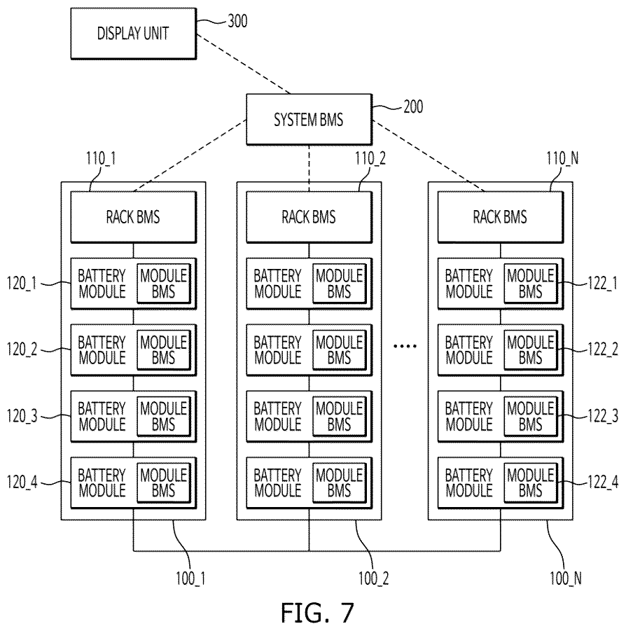

FIG. 7 illustrates a conceptual diagram illustrating a system for monitoring a status of a battery, including a display unit, according to an embodiment of the present disclosure.

The system for monitoring a status of a battery may further include a display unit 300 connected to the system BMS 200 and configured to display identifier information of the detected suspected abnormal cell. The system BMS 200 may include a communication module capable of communicating with the display unit 300. The display unit 300 may be a device that may be connected to the system BMS 200 via a communication network to enable communication and may receive data from the system BMS 200 via the communication network and display the received data. The identifier information of the suspected abnormal cell may be a measurement value (e.g., rack number to which the cell belongs, battery module number, etc.) received from the module BMSs 122_1, 122_2, 122_3, and 122_4.

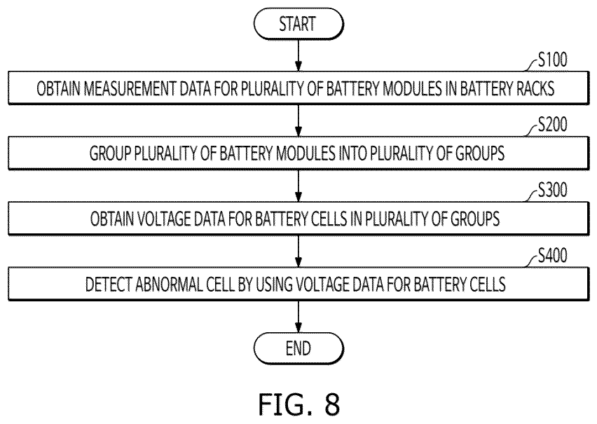

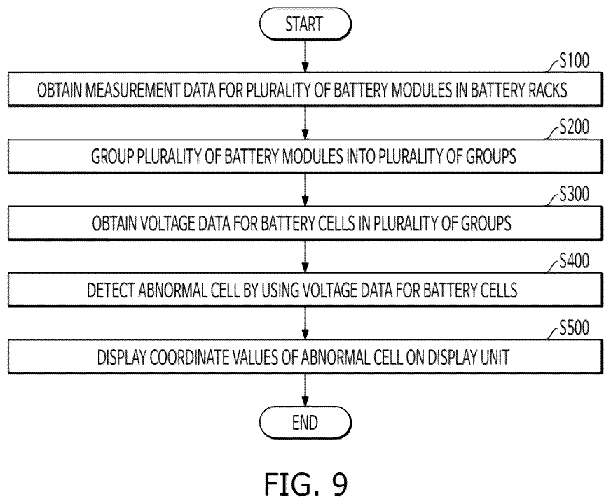

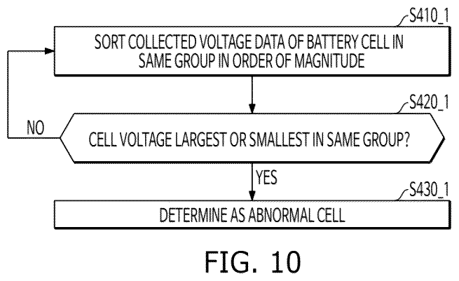

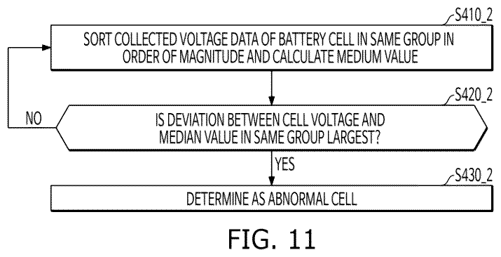

FIG. 8 illustrates a flowchart showing a method for monitoring a status of a battery according to an embodiment of the present disclosure, and FIG. 9 illustrates a flowchart showing a method for monitoring a status of a battery according to another embodiment of the present disclosure. In addition, FIG. 10 illustrates a detailed flowchart showing an embodiment of an abnormal cell detection step in the method for monitoring a status of a battery illustrated in FIG. 8, and FIG. 11 illustrates a detailed flowchart illustrating another embodiment of an abnormal cell detection step in the method for monitoring a status of a battery illustrated in FIG. 8.

A method for monitoring a status of a battery according to an embodiment of the present disclosure may include: obtaining measurement data for a plurality of battery modules 120_1, 120_2, 120_3, and 120_4 included in battery racks 100_1, 100_2, . . . , and 100_N (S100); dividing the battery modules 120_1, 120_2, 120_3, and 120_4 into a plurality of groups, based on the measurement data (S200); obtaining voltage data for each of battery cells in the battery module included in the groups (S300); and detecting a suspected abnormal cell among the battery cells included in the groups, based on the voltage data (S400).

In an embodiment, in the obtaining of the measurement data (S100), the measurement data may include temperature data, and the dividing (S200) may include dividing the battery modules 120_1, 120_2, 120_3, and 120_4 into a plurality of groups, based on a temperature distribution of the temperature data.

More specifically, the dividing (S200) in a case where the measurement data is temperature data may include dividing the battery modules 120_1, 120_2, 120_3, and 120_4 into a plurality of groups at a preset specific temperature interval. In some embodiments, the preset specific temperature interval may be 0.5° C. to 1° C.

In another embodiment, the measurement data in the obtaining of the measurement data (S100) may include SOH data, and the dividing (S200) may include dividing the battery cells 121 into a plurality of groups at a preset specific SOH interval. In some embodiments, the preset specific SOH interval may be 5% to 10%.

The battery modules 120_1, 120_2, 120_3, and 120_4 may be connected through respective rack BMSs 110_1, 110_2, . . . , and 110_N, and the dividing (S200) may include dividing the battery modules 120_1, 120_2, 120_3, and 120_4 connected through the respective rack BMSs 110_1, 110_2, . . . , and 110_N into a plurality of groups. In addition, the respective rack BMSs 110_1, 110_2, . . . , and 110_N may be connected through the system BMS 200, and the dividing (S200) may include dividing may include dividing, by the system BMS 200, the battery modules 120_1, 120_2, 120_3, and 120_4 connected through the respective rack BMSs 110_1, 110_2, . . . , and 110_N into a plurality of groups. The obtaining of the voltage data (S300) may include storing identifier information and voltage data for each of the battery cells 121 in the battery modules 120_1, 120_2, 120_3, and 120_4.

In an embodiment, the detecting of the suspected abnormal cell (S400) may include: sorting the voltage data in order of magnitude within a same group, based on the voltage data obtained in the obtaining of the voltage data (S300) (S410_1); determining whether the voltage data sorted in the sorting of the voltage data in order of magnitude is a maximum value or a minimum value (S420_1); and determining a memory cell as a suspected abnormal cell in a case where it is determined that the voltage data corresponds to the maximum value or the minimum value (S430_1).

In another embodiment, the detecting of the suspected abnormal cell (S400) may include: calculating a median value of the voltage data within a same group, based on the voltage data obtained in the obtaining of the voltage data (S300) (S410_2); determining whether a deviation from the median value of the voltage data calculated in the calculating of the median value is largest (S420_2); and determining a memory cell as a suspected abnormal cell in a case where the deviation from the median value of the voltage data is determined to be the largest (S430_2).

In another embodiment, the detecting of the suspected abnormal cell (S400) may include: calculating a voltage deviation between maximum voltage data and minimum voltage data within a same group, based on the voltage data obtained in the obtaining of the voltage data (S300); and determining a memory cell as a suspected abnormal cell in a case where the voltage deviation calculated in the calculating of the voltage deviation is greater than a preset reference value. At this time, in a case where there is a battery cell in the same group whose voltage deviation increases during charging and discharging of the battery, it may be determined as a suspected abnormal cell. The method for monitoring a status of a battery may further include, after the detecting of the suspected abnormal cell (S400), displaying identifier information (e.g., rack number, battery module number, etc.) of the detected suspected abnormal cell on a display unit.

Although the present disclosure has been described with reference to embodiments and drawings illustrating aspects thereof, the present disclosure is not limited thereto. Various modifications and variations can be made by a person skilled in the art to which the present disclosure belongs within the scope of the technical spirit of the present disclosure and the claims and their equivalents, below.

What is claimed is:

1. A method for monitoring a status of a battery, the method comprising:
obtaining measurement data for a plurality of battery modules included in a battery rack;
dividing the battery modules into a plurality of groups, based on the measurement data;
obtaining voltage data for each battery cell in each battery module included in the plurality of groups; and
detecting a suspected abnormal cell among the battery cells included in the plurality of groups, based on the voltage data.

2. The method as claimed in claim 1, wherein the measurement data comprises temperature data, and
the dividing comprises dividing the battery modules into a plurality of groups, based on a temperature distribution of the temperature data.

3. The method as claimed in claim 1, wherein the measurement data comprises temperature data, and
the dividing comprises dividing the battery modules into a plurality of groups at a preset temperature interval.

4. The method as claimed in claim 3, wherein the preset temperature interval is 0.5° C. to 1° C.

5. The method as claimed in claim 1, wherein the measurement data comprises state of health (SOH) data, and
the dividing comprises dividing the battery cells into a plurality of groups at a preset SOH interval.

6. The method as claimed in claim 5, wherein the preset SOH interval is 5% to 10%.

7. The method as claimed in claim 1, wherein the detecting of the suspected abnormal cell comprises:
sorting the voltage data in order of magnitude within a same group, based on the voltage data obtained in the obtaining of the voltage data;
determining whether the voltage data for a memory cell sorted in the sorting of the voltage data in order of magnitude is a maximum value or a minimum value; and
determining the memory cell as a suspected abnormal cell in a case where it is determined that the voltage data of the memory cell corresponds to the maximum value or the minimum value.

8. The method as claimed in claim 1, wherein the detecting of the suspected abnormal cell comprises:
calculating a median value of the voltage data within a same group, based on the voltage data obtained in the obtaining of the voltage data;
determining whether a deviation from the median value of the voltage data calculated in the calculating of the median value is largest for a memory cell; and
determining the memory cell as a suspected abnormal cell in a case where the deviation from the median value of the voltage data for the memory cell is determined to be largest.

9. The method as claimed in claim 1, wherein the detecting of the suspected abnormal cell comprises:
calculating a voltage deviation between voltage data for a memory cell and maximum voltage data and minimum voltage data within a same group, based on the voltage data obtained in the obtaining of the voltage data; and
determining the memory cell as a suspected abnormal cell in a case where the voltage deviation calculated in the calculating of the voltage deviation is greater than a preset reference value.

10. The method as claimed in claim 1, wherein the obtaining of the voltage data comprises storing identifier information and voltage data for each battery cell in the battery modules.

11. The method as claimed in claim 1, wherein the battery modules are connected through respective rack battery management systems (BMSs), and
the dividing comprises dividing the battery modules connected through the respective rack BMSs into a plurality of groups.

12. The method as claimed in claim 11, wherein the respective rack BMSs are connected through a system BMS, and
the dividing comprises dividing, by the system BMS, the battery modules connected through the respective rack BMSs into a plurality of groups.

13. The method as claimed in claim 1, further comprising, after the detecting of the suspected abnormal cell, displaying identifier information of the detected suspected abnormal cell on a display unit.

14. A system for monitoring a status of a battery, the system comprising:
at least one battery rack for a plurality of battery modules in which a plurality of battery cells are electrically connected, and at least one rack battery management system (BMS) configured to manage charging and discharging of the plurality of battery modules; and
a system BMS connected to the at least one rack BMS and configured to divide the plurality of battery modules included in the at least one battery rack into a plurality of groups and detect a suspected abnormal cell.

15. The system as claimed in claim 14, wherein the system BMS comprises:
a data collection unit configured to obtain measurement data for the plurality of battery modules;
a grouping unit configured to divide the plurality of battery modules into a plurality of groups, based on the measurement data;
an abnormal cell detection unit configured to obtain voltage data for each battery cell included in the groups and detect a suspected abnormal cell among the battery cells included in the groups, based on the voltage data.

16. The system as claimed in claim 15, wherein the measurement data comprises temperature data, and
the grouping unit is configured to divide the battery modules into a plurality of groups at a preset temperature interval.

17. The system as claimed in claim 15, wherein the measurement data comprises state of health (SOH) data, and
the grouping unit is configured to divide the battery cells into a plurality of groups at a preset SOH interval.

18. The system as claimed in claim 15, wherein the abnormal cell detection unit is configured to detect a suspected abnormal cell based on voltage data for each battery cell in each battery module included in a same group.

19. The system as claimed in claim 14, wherein each battery module comprises a module BMS configured to measure physical quantities of the battery cells and transmit measured data to the at least one rack BMS.

20. The system as claimed in claim 15, further comprising a display unit connected to the system BMS and configured to display identifier information of the detected suspected abnormal cell.
